(19) United States
(12) Patent Application Publication
(10) Pub. No.: US 2023/0299654 A1
(43) Pub. Date: Sep. 21, 2023

(54) DEVICE AND METHOD FOR DETECTING ALTERNATING VOLTAGE

(71) Applicant: Weidmüller Interface GmbH & Co. KG, Detmold (DE)

(72) Inventors: GRÖNE Niklas, Lügde (DE); GERKENS Michael, Bielefeld (DE)

(21) Appl. No.: 18/041,347

(22) PCT Filed: Aug. 17, 2021
(86) PCT No.: PCT/EP2021/072851

§ 371 Date: Feb. 10, 2023

(30) Foreign Application Priority Data
Aug. 18, 2020 (DE) 10 2020 121 643.2

(51) Int. Cl. H02M 1/00; H02M 1/08; H02M 3/158

(52) U.S. Cl. CPC H02M 1/0016; H02M 1/083; H02M 3/158

(57) ABSTRACT

A device for detecting alternating voltage includes input terminals for the application of an alternating voltage to be detected and output terminals, at which application of the alternating voltage is indicated. The input terminals and the output terminals are galvanically separated from each other by a coupler. A control element of the coupler is supplied with operating current from the applied alternating voltage, and a switching element of the coupler is connected to the output terminals. The device is characterized by a zero-crossing detector for the alternating voltage to be detected, which zero-crossing detector supplies the control element of the coupler with the operating current in pulses. A method for detecting alternating voltage is obtained through use of the device.

This application is a § 371 national stage entry of International Patent Application No. PCT/EP 2021/072851 filed Aug. 17, 2021. Application No. PCT/EP 2021/072851 claims priority of DE 2020 121 043.2 filed Aug. 18, 2020. The entire content of these applications is incorporated herein by reference.

### BACKGROUND OF THE INVENTION

The invention relates to a device for detecting alternating voltage including input terminals for the application of an alternating voltage to be detected and output terminals at which application of the alternating voltage is indicated. The input terminals and the output terminals are galvanically separated from each other by a coupler, wherein a control element of the coupler is supplied with operating current from the applied alternating voltage, and a switching element of the coupler is connected to the output terminals. The invention also relates to a method for detecting alternating voltage which can be carried out with the aforementioned device.

Such devices are used to be able to check an electrical installation for the presence of alternating voltage at specific nodes in the installation in that the output terminals are searched by a higher-level monitoring apparatus for example. A frequent application is ascertaining the correct operating mode of, for example, relays or contactors, circuit breakers, residual current protection apparatuses or load break switches by detecting the presence of the alternating voltage (at the output) at switch contacts and comparing with the specified switching state of the examined device.

The alternating voltage to be detected is generally a low voltage with a voltage of more than 60 V, for example a lighting network voltage. The higher-level monitoring apparatus can be, for example, an industrial automation device employed for monitoring or controlling purposes. The monitoring apparatus can also be a gateway or a data logger via which only monitoring takes place.

The inputs of such monitoring apparatuses are generally set up to register a switching signal or a protective low voltage, for example 12 Volt (V) or 24 V.

The aforementioned device for detecting alternating voltage forwards the information on the presence of the alternating voltage, in a galvanically separated manner, to the monitoring apparatus in the form of a switching signal. An optocoupler with a light-emitting diode (LED) as the control element for galvanic separation is generally employed as a coupler. The light-emitting diode of the optocoupler is supplied with operating current from the applied alternating voltage, so that the switching element of the optocoupler, which is usually a phototransistor, becomes conductive.

In a simple configuration, a series connection made up of the rectifier diode and a series resistor can be used to operate the LED of the optocoupler through the alternating voltage. An ohmic resistor and/or a capacitor, with its alternating current resistance, can serve as a series resistor. While a very simple design is obtained, a power dissipation inthge range of 10 to 100 milliwatts (mW) is incurred on the series resistor of the LED for the optocoupler which causes the device to operate in an energy-inefficient manner. In addition, such an arrangement also detects a direct voltage at the input which is not desired in all applications.

### SUMMARY OF THE INVENTION

An objective of the present invention is therefore to create a device and a method for detecting alternating voltage of the aforementioned type, which, with a simple design and robust mode of operation, functions as energy-efficiently as possible with low power dissipations and selectively recognizes alternating voltage.

An inventive device of the aforementioned type has a zero-crossing detector for the alternating voltage to be detected, which supplies the control element of the coupler with the operating current in pulses. According to the invention, the device functions in a particularly energy-efficient manner in that the switching element is not permanently connected when the alternating voltage is applied, but rather, with the aid of the zero-voltage detector, is only briefly connected every so often. In addition, only alternating current, and not direct current, is detected in this manner. If, for example, after a zero crossing is detected, the switching element is connected only for a period of 10% of the alternating voltage's half-wave subsequent to the zero crossing, this results in a 90% saving on the energy required in order to actuate the switching element, compared to sustained actuation of the switching element.

The galvanically separating coupler can function inductively, capacitively or optically, and in particular can be formed by an optocoupler. In this case, the control element is a light-emitting diode.

In a preferred embodiment of the device, an input voltage converter, which converts the alternating voltage into an alternating voltage or pulsed direct voltage with a smaller voltage value, is connected upstream of the zero-voltage detector. The zero-voltage detector can be constructed at lower voltage at less expense. The input voltage converter can have a rectifier with at least one capacitor connected upstream and/or series resistor connected upstream. In particular, through the specified combination of a rectifier, capacitor and series resistor it is possible to construct an inexpensive voltage converter with relatively small power dissipations. At least one bridge rectifier is preferably used as a rectifier.

In a further embodiment of the device, the zero-voltage detector has a diode and a smoothing capacitor, in order to form at its input from the alternating voltage or the pulsed direct voltage, a direct voltage for supplying the control element. A switching transistor is connected in series, with its switching path, to the control element, with a control input of the switching transistor being coupled to the alternating voltage or the pulsed direct voltage at the input of the zero-voltage converter. The switching transistor is actuated such that it connects through only in the region of the zero crossing.

In a further embodiment of the device, its output terminals are connected to the terminals of a phototransistor of the coupler designed as an optocoupler. The pulsing or switching state of the phototransistor can then be interrogated at the output terminals. It should be born in mind that the switching state is observed over a period of at least one half (or the entire) period duration of the alternating voltage in order to ascertain whether alternating voltage is being applied to the input terminals. In a digital evaluation of the switching state of the phototransistor via a microcontroller, for example, this can be easily implemented in a program-controlled manner.

According to a further embodiment of the device, an RC element is arranged parallel to the terminals of the phototransistor of the optocoupler.

The signal which can be tapped at the output terminals is subjected to analog smoothing through the RC element, as a result of which it is possible to conclude without difficulty, even without evaluation by a microcontroller, whether an input alternating voltage is or is not being applied. In alternative configurations, other time elements (which function in an analog or digital manner) can be used to provide a signal at the output terminals which has a specific level as constantly as possible if alternating voltage is being applied to the input terminals and which has a level which deviates from this if no alternating voltage is being applied to the input terminals.

A method according to the invention serves to detect alternating voltage with a device which includes input terminals for the application of an alternating voltage to be detected and output terminals at which application of the alternating voltage is indicated. In this case, the input terminals and the output terminals are galvanically separated from each other by a coupler, wherein a control element of the coupler is supplied with operating current from the applied alternating voltage, and a switching element of the coupler is connected to the output terminals. The method is characterized in that the control element of the coupler is supplied with operating current in pulses, with one pulse time parameter being dependent on a zero crossing of the alternating voltage. The pulse time parameter is considered as a starting point in time, an end point in time and/or a pulse length here. The method can be carried out with the previously described device, for example, to provide the advantages specified above in connection with the device.

### BRIEF DESCRIPTION OF THE FIGURES

The invention will be explained in greater detail below with the aid of the accompanying drawing figures, in which.

FIG. 1 is a schematic block diagram of a device for detection of alternating voltage; and

FIG. 2 is a more detailed block diagram of a further device for detection of alternating voltage.

### DETAILED DESCRIPTION

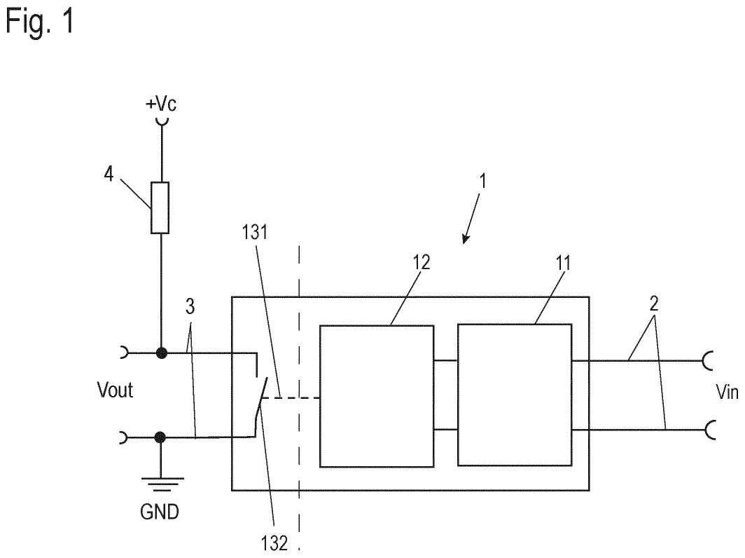

FIG. 1 shows an embodiment of a device 1 for detection of alternating voltage in a block diagram.

The device 1 has input terminals 2 at which an alternating voltage Vin to be detected can be applied. The device 1 also has two floating output terminals 3 which are galvanically separated from the input terminals 2, which is indicated by the dashed line in FIG. 1.

Via the output terminals 3, a higher-level monitoring apparatus can interrogate whether the alternating voltage Vin is being applied to the input terminals 2. Due to the galvanic separation, the interrogation can be performed at a voltage level which is independent of the voltage level of the alternating voltage Vin, in particular at the level of a smallest direct voltage. The alternating voltage Vin at the input terminals 2 is generally an alternating low voltage with a voltage level of 60 V or more.

In the example of the device 1 shown in FIG. 1, the output terminals are connected to a switching element 132 which is symbolically depicted as a switch. In order to generate a voltage signal for the higher-level monitoring apparatus, one of the output terminals 3 is coupled to a ground terminal GND and the other output terminal 3 is connected to a positive potential Vc via a pull-up resistor 4. This potential Vc can be provided by the higher-level monitoring device, for example. In such a configuration, the output terminals 3 form a voltage output to which a voltage Vout is applied depending on the switch position of the switching element 132. Due to the nature of the arrangement of the pull-up resistor 4. Vout is approximately equal to Vc when the switching element 132 is not connected and is approximately zero when the switching element 132 is connected to be conductive.

By way of example, the device 1 can be employed in order to check whether a power supply line connected by a relay or contactor, a circuit breaker, a residual current protection apparatus or a load break switch is actually conducting voltage. By comparing the voltage signal Vout to a specified switching state of the specified device, it is possible to check the correct functioning of the device.

According to the application, the device 1 functions in a particularly energy-efficient manner in that the switching element 132 is not permanently connected when the alternating voltage is applied, but rather is only connected in a conducting manner for a brief time once per half-wave of the alternating voltage Vin with the aid of a zero-voltage detector 12. For example, the switching element 132 is connected only for a millisecond (ms) or less in a conducting manner after a zero cross is detected. Thus, a pulse time parameter, in this case the beginning of a pulse, is made dependent upon a zero cross being detected. An alternating voltage of an assumed frequency of 50 Hz has a period duration of 20 ms and correspondingly a zero cross every 10 ms. If the switching element 132 is then in each case only connected for 1 ms for example, only 10% of the switching energy is required for the switching element 132 compared to continuous switching.

In the example in FIG. 1 an input voltage converter 11 which converts the alternating voltage Vin into a lower alternating voltage (or a pulsing direct voltage) is connected upstream of the zero-voltage detector 12. The zero-voltage detector 12 is then supplied with this lower alternating voltage. Since a phase shift can be introduced by the input voltage converter 12, the switching element 132 is not necessarily connected in the zero cross of the alternating voltage Vin, but rather once per half-wave or once per period duration depending on whether a zero cross is detected when voltage is falling and increasing or only either when voltage is falling or when it is increasing.

The signal Vout pulses through the zero-voltage detector 12. When the signal Vout is registered at the output terminals 3, it must be borne in mind in this regard that measurement is performed for longer than a half (or entire) period duration of the alternating voltage as to whether the signal Vout is equal to zero. If the signal Vout is equal to zero at any point in time within a duration of more than a half (or entire) period duration, the alternating voltage Vin is being applied. Only if a signal Vout different than zero is recognized for at least a half (or entire) period duration can it be concluded that no alternating voltage Vin is being applied to the input terminals 2. When evaluating the signal Vout as a digital signal via a microcontroller, for example, this can easily be registered in a program-controlled manner.

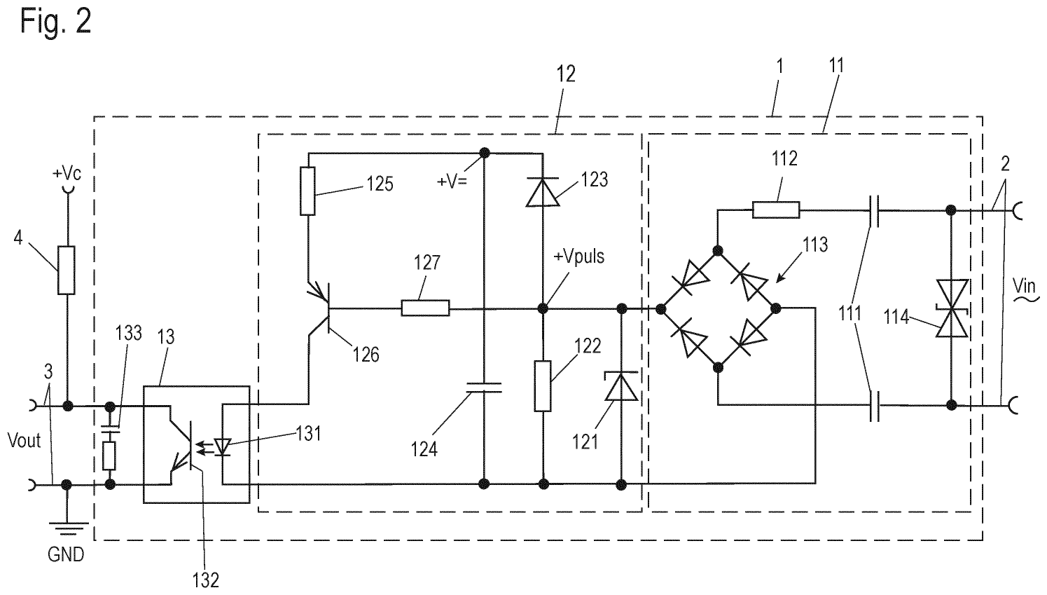

In an alternative configuration, an RC element with a time constant adapted to the period duration of the input alternating voltage Vin, which performs smoothing of the signal Vout, can be arranged at the output terminals 3. When the alternating voltage Vin is applied, the signal Vout then falls with the time constant to a minimum value close to zero. If the alternating voltage Vin is no longer being applied, the signal Vout rises with this time constant to a maximum value close to Vc. An embodiment in which an appropriate RC element is already integrated into the device 1 is shown in FIG. 2.

FIG. 2 shows a second embodiment of a monitoring device 1 in a more detailed block diagram than FIG. 1. Up to the previously discussed RC element, the circuit construction from FIG. 2 can be transferred to the embodiment from FIG. 1. The external circuit of the device 1 is, in FIG. 2, analogous to that in FIG. 1.

In the device 1 according to FIG. 2, the coupler 13 is, by way of example, an optocoupler, which will also be referred to as an optocoupier 13 below. The switching element 132 is a phototransistor of the optocoupier 13. Parallel to the switching path of the phototransistor, there is connected an RC element 133 which serves to smooth the output signal Vout and includes a capacitor and a resistor in series connection. Alternatively to the optocoupler 13, a coupler which functions on another transmission principle, for example a coupler which functions inductively or capacitively, can also be employed.

The optocoupler 13 has a light-emitting diode (LED) as a control element 131, which connects the phototransistor, i.e. the switching path 132, in a conductive manner when current is flowing. The control element 131 will also be referred to below as an LED 131. The LED 131 is supplied with operating current in a pulsing manner via a zero-crossing detector 12. An input voltage converter 11 is connected upstream of the zero-crossing detector 12 as an input stage, which zero-crossing detector 12 is supplied by the applied alternating voltage Vin.

In the present case, the input voltage converter 11 is constructed like a capacitor network part having two capacitors 111 which are directly connected to the input terminals 2, in series connection with a series resistor 112 and a bridge rectifier 113. Alternatively, an arrangement with one or more resistors without a capacitor can be employed instead of the combination of capacitors and resistors. Several resistors can be connected as voltage dividers or like a cascade. An input voltage converter designed only with resistors entails greater losses, but it does have greater ability to withstand excess voltage. An optional suppressor diode connected in parallel to the input terminals 2 serves as a protective element 114 against brief high voltage pulses at the input terminals 2.

A Zener diode 121 and a resistor 122 are connected in parallel to outputs of the bridge rectifier 113. A pulsing voltage Vpuls, the time progression of which corresponds to strung-together half-waves of the alternating voltage Vin, is applied to this parallel circuit, wherein negative half-waves are in each case “flipped up” by the bridge rectifier 113. The voltage Vpuls is placed on a smoothing capacitor 124 via a diode 123, which smoothing capacitor 124 appropriately charges up to a direct voltage Vin, the level of which corresponds to the amplitude of the voltage Vpuls.

The capacitor 124 is connected via a series resistor 125 and a transistor 126 to the LED 131 of the optocoupler 13. In the example depicted, the transistor 126 is a PNP bipolar transistor whose control input is connected via a further series resistor 127 to the nodes onto which the pulsing voltage Vpuls is applied.

If a positive voltage is applied to these nodes, i.e. during a half-wave of the pulsing voltage Vpuls, the transistor 126 blocks and the capacitor 124 charges up to the voltage Vin. As soon as the voltage Vpuls falls to a value close to zero, the transistor 126 becomes conductive and the capacitor 124 discharges via the series resistor 125, the transistor 126 and the LED 131, which lights up appropriately and conductively connects the switching element 132. As soon as the voltage Vpuls rises again, the transistor 126 blocks once again and extinguishes the LED 131. This applies at least when the capacitance of the smoothing capacitor 124 is large enough that the smoothing capacitor 124 is able to supply the LED 131 with operating current until the transistor 126 blocks again. The capacitance of the smoothing capacitor 124 can also be selected such that the light duration of the LED 131 is limited by the stored energy in the smoothing capacitor 124 and the LED 131 is already extinguished when the transistor 126 is blocked again via its control input.

In any case, the light duration of the LED 131 will be brief compared to the half period duration of the alternating voltage Vin. As is stated in connection with FIG. 1, a light duration can be set in the range of milliseconds or below.

While the LED 131 lights up, the phototransistor (switching element 132) becomes conductive and discharges the capacitor of the RC element 133. A minimum voltage Vout which indicates the existence of the alternating voltage Vin is then set at the output terminals 3. If the LED 131 does not light up over a relatively long time (a number of period durations), the voltage Vout at the output terminals 3 increase, which indicates that no alternating voltage Vin is being applied to the input terminals.

1-12. (canceled)

13. A device for detecting alternating voltage, comprising
(a) input terminals for the application of an alternating voltage to be detected and output terminals at which application of the alternating voltage is indicated;
(b) a coupler arranged between and galvanically separating said input and output terminals, said coupler including a control element supplied with operating current from the applied alternating voltage, and a switching element connected with said output terminals; and
(c) a zero-crossing detector for the alternating voltage to be detected, said zero-crossing detector supplying said control element with the operating current in pulses.

14. The device according to claim 13, in which said coupler operates one of inductively, capacitively and optically.

15. The device according to claim 14, in which said coupler is an optocoupler and said control element is a light-emitting diode.

16. The device according to claim 13, and further comprising an input voltage converter connected upstream of said zero-crossing detector, said input voltage converter converting the alternating voltage into a pulsed direct voltage with a smaller voltage value.

17. The device according to claim 16, wherein said input voltage converter includes a rectifier having at least one capacitor and series resistor connected upstream.

18. The device according to claim 17, wherein said rectifier comprises at least one bridge rectifier.

19. The device according to claim 13, wherein said zero-voltage detector includes a diode and a smoothing capacitor in order to form a direct voltage from the alternating voltage for supplying the control element.

20. The device according to claim 13, wherein said zero-voltage detector includes a switching transistor having a switching path connected in series with said control element and a control input coupled to the alternating voltage at its input.

21. The device according to claim 15, in which the output terminals are connected with terminals of a phototransistor of said optocoupier.

22. The device according to claim 21, and further comprising a resistor capacitor element arranged parallel to said terminals of said phototransistor of said optocoupler (13).

23. A method for detecting alternating voltage, with a device having input terminals for the application of an alternating voltage to be detected and output terminals at which application of the alternating voltage is indicated, the input terminals and the output terminals being galvanically separated from each other by a coupler, and a control element of the coupler being supplied with operating current from the applied alternating voltage, a switching element of the coupler being connected to the output terminals, comprising the step of supplying the control element of the coupler with the operating current in pulses, wherein a pulse time parameter is dependent upon a zero cross of the alternating voltage.

24. The method according to claim 23, in which the pulse time parameter is one of a point in time of a beginning of one of the pulses, a point in time of an end of one of the pulses and a length of the pulses.
